(19) United States
(12) Patent Application Publication
(10) Pub. No.: US 2024/0333298 A1
(43) Pub. Date: Oct. 3, 2024

(54) SUCCESSIVE APPROXIMATION TYPE A/D CONVERTER

(71) Applicant: ROHM Co., LTD., Kyoto (JP)

(72) Inventor: Haruaki Nakamura, Kyoto (JP)

(21) Appl. No.: 18/613,255

(22) Filed: Mar. 22, 2024

(30) Foreign Application Priority Data
Mar. 28, 2023 (JP) 2023-052372

(51) Int. Cl. H03M 1/46; H03M 1/12; H03M 1/40

(52) U.S. Cl. CPC H03M 1/46; H03M 1/125; H03M 1/403

(57) ABSTRACT

Provided is a successive approximation type analog/digital converter for generating a digital output signal corresponding to an analog input signal, including a capacitive digital/analog converter including a plurality of capacitors covering the most significant bit through the least significant bit, sampling an analog signal corresponding to the input signal, and generating an analog output signal corresponding to a digital input, a comparator performing successive approximation of the analog output signal for the most significant bit through the least significant bit with a comparison reference voltage, and a control circuit generating the digital input corresponding to a result of the successive approximation by the comparator and generating the digital output signal corresponding to the sampled analog signal corresponding to the result of the successive approximation by the comparator.

### CROSS REFERENCE TO RELATED APPLICATIONS

This application claims priority benefit of Japanese Patent Application No. JP 2023-052372 filed in the Japan Patent Office on Mar. 28, 2023. Each of the above-referenced applications is hereby incorporated herein by reference in its entirety.

### BACKGROUND

The present disclosure relates to a successive approximation type analog/digital (A/D) converter.

As a type of an A/C converter converting an analog input signal to a digital output signal, there has been known a successive approximation type A/D converter (also referred to as “successive approximation type ADC” hereunder). In the case of a successive approximation type ADC equipped with a capacitive digital/analog (DA) converter (also referred to as “capacitive DAC” hereunder), the ADC causes the capacitive DAC to sample an analog signal corresponding to the analog input signal. A comparator is then used to perform successive approximation of the sampled signal and a reference signal. Then, the output digital signal corresponding to the result of the successive approximation by the comparator is generated.

An example of the related art is disclosed in Japanese Patent Laid-Open No. 2017-192099.

### BRIEF DESCRIPTION OF THE DRAWINGS

FIG. 1 is a circuit diagram of a successive approximation type ADC as one embodiment of the present disclosure;

FIG. 2 is a schematic diagram depicting the state of the successive approximation type ADC determining the most significant bit;

FIG. 3 is a schematic diagram depicting the state of the successive approximation type ADC having terminated a successive approximation;

FIG. 4 is a schematic diagram depicting the state of the successive approximation type ADC before the next sampling;

FIG. 5 is a circuit diagram of a successive approximation type ADC of a comparative technology;

FIG. 6 is a schematic diagram depicting the state of the successive approximation type ADC of the comparative technology having terminated a successive approximation; and

FIG. 7 is a schematic diagram depicting the state of the successive approximation type ADC of the comparative technology at the time of the next sampling.

### DETAILED DESCRIPTION

### Outline

Some exemplary embodiments of the present disclosure are outlined here. This outline is intended to provide a basic understanding of the embodiments as an introduction to the ensuing detailed description by explaining several simplified concepts of one or multiple embodiments. As such, the outline is not limitative of the scope of the technology or its disclosure. This outline is not intended as a comprehensive overview of all conceivable embodiments, nor is it aimed at identifying the important elements of all embodiments or delineating the range of part or all of the embodiments. For the purpose of explanation, “one embodiment” may be used to designate an embodiment (working example and its variations) or multiple embodiments (working examples and their variations) disclosed in this description.

According to one embodiment of the present disclosure, there is provided a successive approximation type A/D converter for generating a digital output signal corresponding to an analog input signal. The successive approximation type A/D converter includes a capacitive D/A converter including a plurality of capacitors covering the most significant bit through the least significant bit, sampling an analog signal corresponding to the input signal, and generating an analog output signal corresponding to a digital input, a comparator performing successive approximation of the analog output signal for the most significant bit through the least significant bit and a comparison reference voltage, and a control circuit generating the digital input corresponding to a result of the successive approximation by the comparator and generating the digital output signal corresponding to the sampled analog signal corresponding to the result of the successive approximation by the comparator. The capacitive D/A converter samples the analog signal by allowing each of the capacitors to accumulate electrical charges corresponding to the input signal. After the successive approximation by the comparator is performed and before the next sampling by the capacitive D/A converter is performed, the control circuit controls the electrical charges accumulated in each of the capacitors to become substantially equivalent to the electrical charges at the time of the preceding sampling.

With the above configuration, when the analog signal is sampled, the electrical charges accumulated in the capacitors of the capacitive DAC become substantially equivalent to the electrical charges at the time of the preceding sampling. This makes it possible to suppress generation of kickback noise stemming from the electrical charge flows in the capacitors and by the analog signals and thereby to shorten the settling time at the time of sampling.

According to one embodiment, the capacitive D/A converter may further include an input path receiving input of the analog signal. The analog signal may be sampled by having one end of each of the capacitors supplied with the analog signal via the input path. After the successive approximation by the comparator is performed and before the next sampling is performed, the control circuit may cause one end of each of the capacitors to be short-circuited with each other.

According to one embodiment, the successive approximation type ADC may further include an input circuit generating the analog signal, and a switch interposed between the input circuit and the input path. After the successive approximation by the comparator is performed and before the next sampling is performed, with the switch turned off, the control circuit may connect one end of each of the capacitors to the input path.

According to one embodiment, the capacitive D/A converter may further include an output path connected to the other end of each of the capacitors and outputting the analog output signal, and the control circuit may control the capacitive D/A converter in such a manner that the output path is supplied with the comparison reference voltage at the time of the preceding sampling, the output path being further controlled to be supplied with the comparison reference voltage after the successive approximation by the comparator is performed and before the next sampling is performed.

### Embodiment

A preferred embodiment of the present disclosure is described below with reference to the accompanying drawings. The same or equivalent constituent elements, members, and processes indicated in the drawings are designated by the same reference signs, and their duplicate explanations are omitted where appropriate. It is to be noted that the embodiment is only an example and not limitative of the disclosure or the technology and that not all features or their combinations described in the embodiment are necessarily essential for the disclosure and the technology.

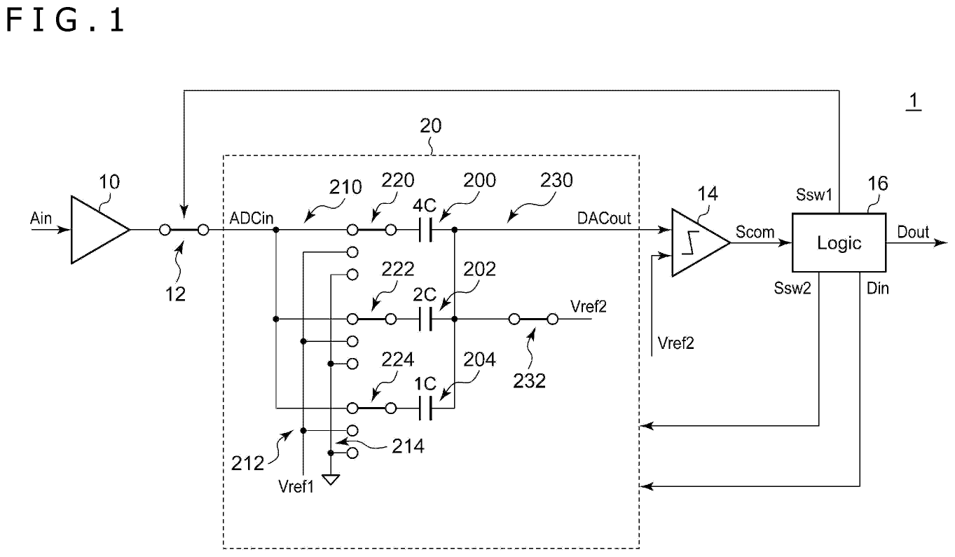

FIG. 1 is a circuit diagram of a successive approximation type ADC 1 as one embodiment of the present disclosure. The successive approximation type ADC 1 of this embodiment is configured to generate a digital output signal Dout in response to an analog input signal Ain. The successive approximation type ADC 1 includes a buffer circuit 10 (input circuit), a switch 12, a comparator 14, a logic circuit 16 (control circuit), and a capacitive DAC 20.

The buffer circuit 10 receives input of the analog input signal Ain and generates an analog signal ADCin corresponding to the analog input signal Ain.

The switch 12 is interposed between the buffer circuit 10 and the capacitive DAC 20. Specifically, the switch 12 is arranged such that one end thereof is connected to the buffer circuit 10 and the other end thereof to the capacitive DAC 20. When the switch 12 is turned on, the capacitive DAC 20 is connected to the buffer circuit 10 to supply the analog signal ADCin to the capacitive DAC 20. With the switch 12 turned off, the capacitive DAC 20 is disconnected from the buffer circuit 10.

The capacitive DAC 20 samples the analog signal ADCin corresponding to the analog input signal Ain, generating an analog output voltage DACout corresponding to a digital input Din. The capacitive DAC 20 of this embodiment includes multiple capacitors 200, 202, and 204, an input path 210, a reference path 212, a ground path 214, multiple selectors 220, 222, and 224, an output path 230, and a switch 232 with respect to the most significant bit through the least significant bit.

The capacitors 200, 202, and 204 correspond to 3 bits. Specifically, the capacitor 200 corresponds to the most significant bit, the capacitor 202 to the second most significant bit, and the capacitor 204 to the least significant bit.

The capacitance values of the capacitors 200, 202, and 204 are “4C,” “2C,” and “1C,” respectively, relative to a reference capacitance value “C.” That is, the capacitors 200, 202, and 204 have their capacitance values weighted by a predetermined factor (=2×C (where x=integer of 0 to 2). Although the capacitive DAC 20 of this embodiment has three capacitors 200, 202, and 204, there may be two or less or four or more capacitors instead. That is, the number of bits in the capacitive DAC 20 may be two or less or four or more.

The capacitor 200 is arranged such that one end thereof is connected to the selector 220 and the other end thereof to the output path 230. The capacitor 202 is arranged such that one end thereof is connected to the selector 222 and the other end thereof to the output path 230. The capacitor 204 is arranged such that one end thereof is connected to the selector 224 and the other end thereof to the output path 230.

The input path 210 is provided in common to the selectors 220, 222, and 224 and connected to the other end of the switch 12. When the switch 12 is turned on, the analog signal ADCin is input from the buffer circuit 10 to the input path 210. The reference path 212 is provided in common to the selectors 220, 222, and 224 and arranged to be supplied with a reference voltage Vref1. The ground path 214 is provided in common to the selectors 220, 222, and 224 and connected to ground.

The selectors 220, 222, and 224 are each configured such that one end of each of the capacitors 200, 202, and 204 is connected to the input path 210, to the reference path 212, or to the ground path 214. The destination to which one end of each of the capacitors 200, 202, and 204 is connected changes according to the digital input Din from the logic circuit 16.

The output path 230 is arranged to be connected to the other end of each of the capacitors 200, 202, and 204 and to output the output signal DACout of the capacitive DAC 20. The switch 232 is arranged such that one end thereof is connected to a common path 20 and the other end thereof is supplied with a comparison reference voltage Vref2. Here, the comparison reference voltage Vref2 may be half the reference voltage Vref1, for example. When the switch 232 is turned on, the output path 230 is supplied with the comparison reference voltage Vref2. When the switch 232 is turned off, the output path 230 is not supplied with the comparison reference voltage Vref2.

The capacitive DAC 20 is configured in such a manner that the multiple capacitors 200, 202, and 204 each accumulate electrical charges corresponding to the analog signal ADCin in order to sample that signal. Specifically, the analog signal ADCin is sampled by having one end of each of the multiple capacitors 200, 202, and 204 supplied with the analog signal ADCin via the input path 210. More specifically, the selectors 220, 222, and 224 connect one end of each of the capacitors 200, 202, and 204 to the input path 210. This allows each of the capacitors 200, 202, and 204 to accumulate electrical charges corresponding to the analog signal ADCin in order to sample it.

The capacitive DAC 20 is configured to generate the output voltage DACout for the most significant bit through the least significant bit. Specifically, the capacitive DAC 20 is configured to generate the output voltage DACout to determine 0 or 1 in the most significant bit through the least significant bit for the digital output signal Dout to be generated. The output signal DACout is generated every time the connections of the selectors 220, 222, and 224 are changed in response to the digital input Din.

The comparator 14 compares the output signal DACout of the capacitive DAC 20 with the comparison reference voltage Vref2, and generates a signal Scom reflecting the result of the comparison. Specifically, the comparator 14 performs successive approximation between the output voltage DACout and the comparison reference voltage Vref2 for each of the most significant bit through the least significant bit, and generates the signal Scom reflecting the result of each successive approximation.

In response to the result of the comparison by the comparator 14 (specifically, the signal Scom), the logic circuit 16 generates the digital input Din accordingly. Given the result of the successive approximation by the comparator 14, the logic circuit 16 generates a digital output signal Dout accordingly. The logic circuit 16 may generate a signal Ssw1 to control the on/off of the switch 12 and a signal Ssw2 to control the on/off of the switch 232.

After the successive approximation by the comparator 14 is performed and before the next sampling by the capacitive DAC 20 is performed, the logic circuit 16 controls the electrical charges accumulated in the multiple capacitors 200, 202, and 204 to become substantially equivalent to the electrical charges at the time of the preceding sampling. In this embodiment, the logic circuit 16 causes one end of each of the multiple capacitors 200, 202, and 204 to be short-circuited with each other after the successive approximation by the comparator 14 is performed and before the next sampling is performed.

Specifically, after the successive approximation by the comparator 14 is performed and before the next sampling is performed, with the switch 12 turned off, the logic circuit 16 connects one end of each of the multiple capacitors 200, 202, and 204 to the input path 210. At this time, the logic circuit 16 transmits the signal Ssw1 to the switch 12 to turn it off, and sends the digital input Din to the capacitive DAC 20 such that one end of each of the capacitors 200, 202, and 204 is connected to the input path 210.

The logic circuit 16 controls the capacitive DAC 20 in such a manner that at the time of the preceding sampling, the comparison reference voltage Vref2 is supplied to the output path 230 and that, after the successive approximation by the comparator 14 is performed and before the next sampling is performed, the comparison reference voltage Vref2 is supplied to the output path 230. Specifically, at the time of each sampling, the logic circuit 16 transmits the signal Ssw2 to the switch 232 to turn it on.

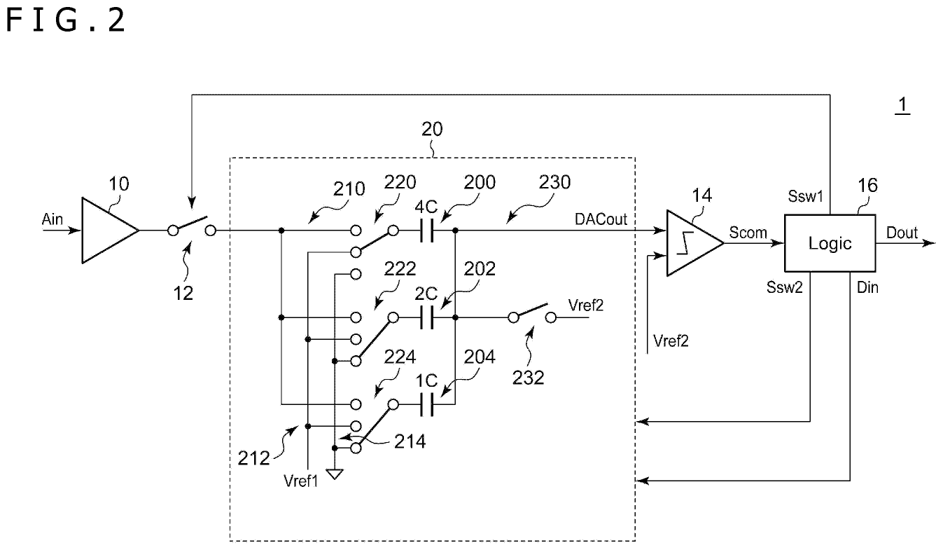

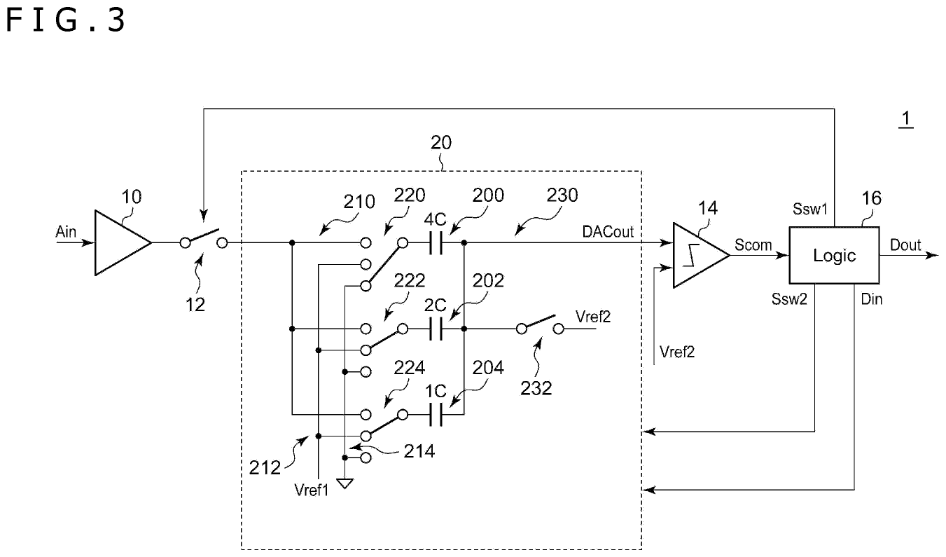

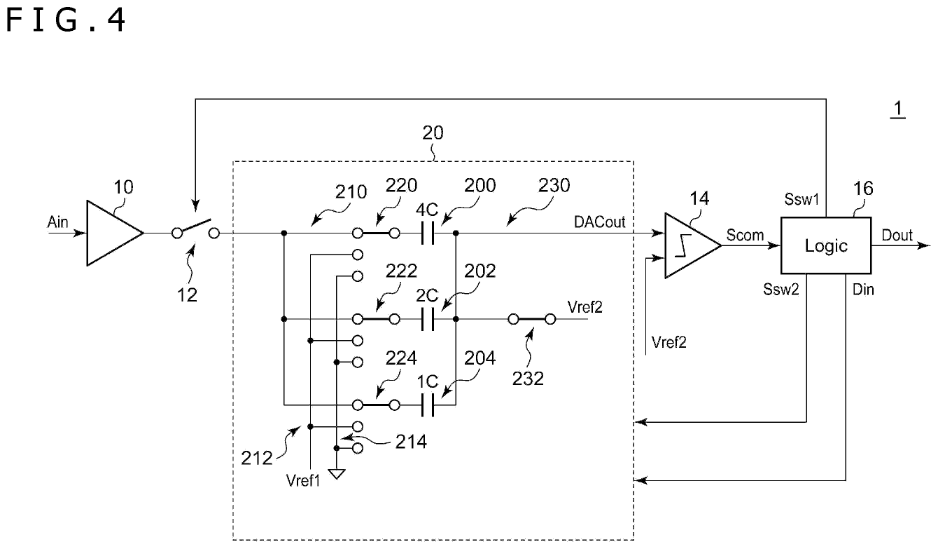

The flow of operations of the successive approximation type ADC 1 of this embodiment is described below with reference to FIGS. 1 through 4. FIG. 2 is a schematic diagram depicting the state of the successive approximation type ADC 1 determining the most significant bit. FIG. 3 is a schematic diagram depicting the state of the successive approximation type ADC 1 having terminated the successive approximation. FIG. 4 is a schematic diagram depicting the state of the successive approximation type ADC 1 before the next sampling.

First, the capacitive DAC 20 samples the analog signal ADCin. It is assumed here that the analog input signal Ain is a signal corresponding to 3 in hexadecimal (011). At this time, as depicted in FIG. 1, the switch 12 is turned on to have the analog signal ADCin input to the input path 210. The switch 232 is also turned on to have the comparison reference voltage Vref2 supplied to the output path 230. Further, one end of each of the capacitors 200, 202, and 204 is connected to the input path 210 via the selectors 220, 222, and 224 respectively, and the capacitors 200, 202, and 204 accumulate the electrical charges therein corresponding to the analog signal ADCin.

Next, a comparison is made between the output signal of the capacitive DAC 20 and the comparison reference voltage so as to determine the most significant bit. At this time, as depicted in FIG. 2, the switch 12 is turned off from the on-state to disconnect the path that leads from the buffer circuit 10 to the capacitive DAC 20. The switch 232 is also turned off. Further, the connections of the selectors 220, 222, and 224 are changed in response to the digital input Din in such a manner that one end of the capacitor 200 is connected to the reference path 212 and one end of each of the capacitors 202 and 204 is connected to the ground path 214.

The comparator 14 compares the output signal DACout of the capacitive DAC 20 at this point with the comparison reference voltage Vref, and transmits to the logic circuit 16 the signal Scom reflecting the result of the comparison. The logic circuit 16 determines the most significant bit according to the signal Scom, and generates the digital input for determining the next most significant bit.

Next, the comparator 14 makes a comparison between the comparison reference voltage and the output signal of the capacitive DAC 20 corresponding to the digital input Din for determining the second most significant bit. The comparator 14 then transmits the signal reflecting the result of the comparison to the logic circuit 16. According to the transmitted signal, the logic circuit 16 inputs to the capacitive DAC 20 the digital input for determining the least significant bit. The comparator 14 makes a comparison between the comparison reference voltage and the output signal of the capacitive DAC 20 corresponding to the digital input for determining the least significant bit. The comparator 14 then transmits the signal reflecting the result of the comparison to the logic circuit 16.

In this manner, the comparator 14 performs a successive approximation between the comparison reference voltage and the output signal for each of the most significant bit through the least significant bit. The logic circuit 16 generates the digital output signal Dout (of 3 bits in this embodiment) reflecting the result of the successive approximation by the comparator 14.

As depicted in FIG. 3, after the successive approximation with this embodiment, the capacitor 200 is connected to the ground path 214, and the capacitors 202 and 204 are each connected to the reference path 212. Consequently, the output signal Dout is 3 in hexadecimal (011). At this time, the switches 12 and 232 are both turned off.

In this embodiment, as depicted in FIG. 4, the connections of the selectors 220, 222, and 224 are then changed in such a manner that one end of each of the capacitors 200, 202, and 204 is connected to the input path 210. The switch 232 is turned on from the off-state. Similar to the preceding sampling explained with reference to FIG. 1, the connection changes cause one end of each of the capacitors 200, 202, and 204 to be interconnected via the input path 210 to let the output path 230 be supplied with the comparison reference voltage Vref2. This allows the electrical charges accumulated in the capacitors 200, 202, and 204 to become substantially equivalent to those at the preceding sampling.

At the time of the next sampling, as depicted in FIG. 1, the switch 12 is turned on from the off-state. This causes the next analog signal ADCin to be input to the input path 210 of the capacitive DAC 20, allowing the analog signal ADCin to be sampled. Just before the switch 12 is turned on from the off-state, the electrical charges at the time of the preceding sampling are accumulated in each of the capacitors 200, 202 and 204. As a result, a difference between the electrical charges accumulated in the capacitors 200, 202 and 204 on one hand and the electrical charges to be accumulated therein at the time of the next sampling on the other hand is small. This makes it possible to suppress kickback noise at the time of the next sampling.

In this manner, the successive approximation type ADC 1 of this embodiment suppresses kickback noise at the time of the sampling and shortens the settling time taken for the sampling. Consequently, the successive approximation type ADC 1 of this embodiment eliminates the need for configuring the buffer circuit 10 to respond rapidly for quick settling, thereby reducing the necessity of increasing the current consumption of the buffer circuit 10 or widening the area allocated thereto.

The smaller the time change in the analog input signal Ain, the smaller the difference in the electrical charges accumulated in the capacitors 200, 202, and 204 between the preceding and the next sampling. Thus, in the successive approximation type ADC 1 of this embodiment, the smaller the time change in the analog input signal Ain, the better the result because the smaller time change reduces generation of the kickback noise. Specifically, the analog input signal Ain may preferably be a direct current (DC) signal or a low-frequency signal.

It is also preferable, as in this embodiment, to input the single analog input signal Ain to the successive approximation type ADC 1 rather than to sequentially select the input signal from multiple analog input signals for input to the successive approximation type ADC 1. That is because the change in the signal input to the successive approximation type ADC 1 is small.

### Comparative Technology

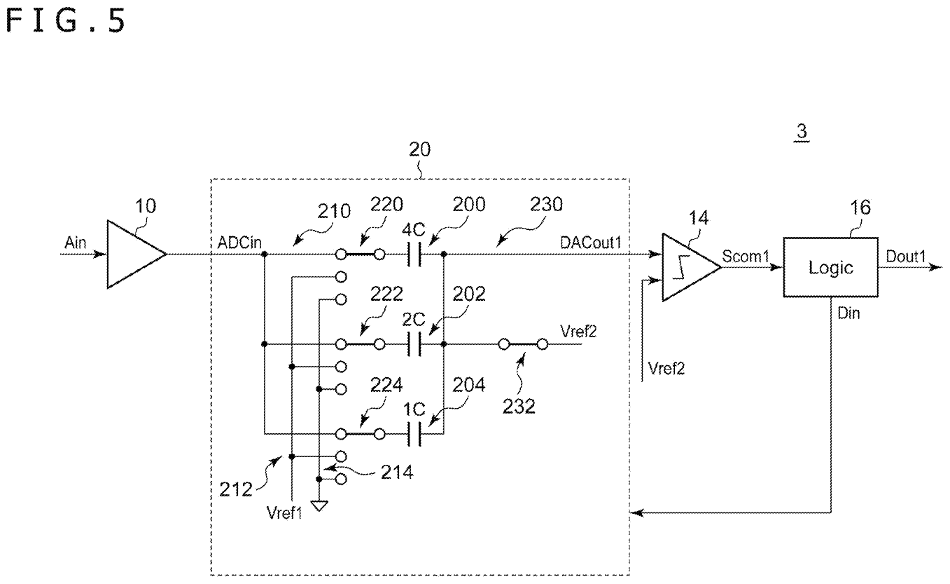

FIG. 5 is a circuit diagram of a successive approximation type ADC 3 of a comparative technology. In FIG. 5, the configurations having substantially identical functions to those of the configurations in the successive approximation type ADC 1 in FIG. 1 are represented by the same reference signs, and their explanations are omitted where appropriate. The successive approximation type ADC 3 of the comparative technology is primarily different from the successive approximation type ADC 1 of the above-described embodiment in that there is no switch 12 connected to the buffer circuit 10. That is, the analog signal ADCin output from the buffer circuit 10 is directly input to a capacitive DAC 20.

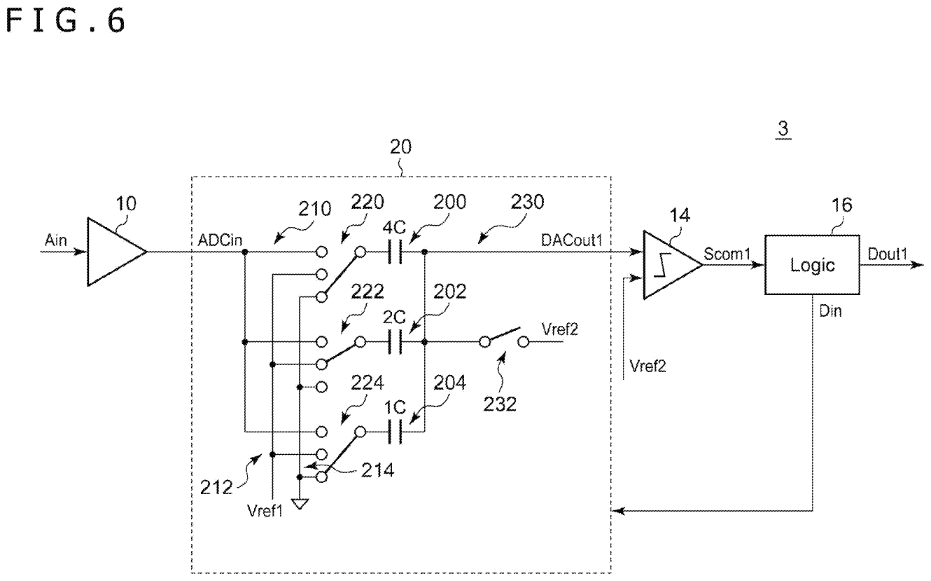

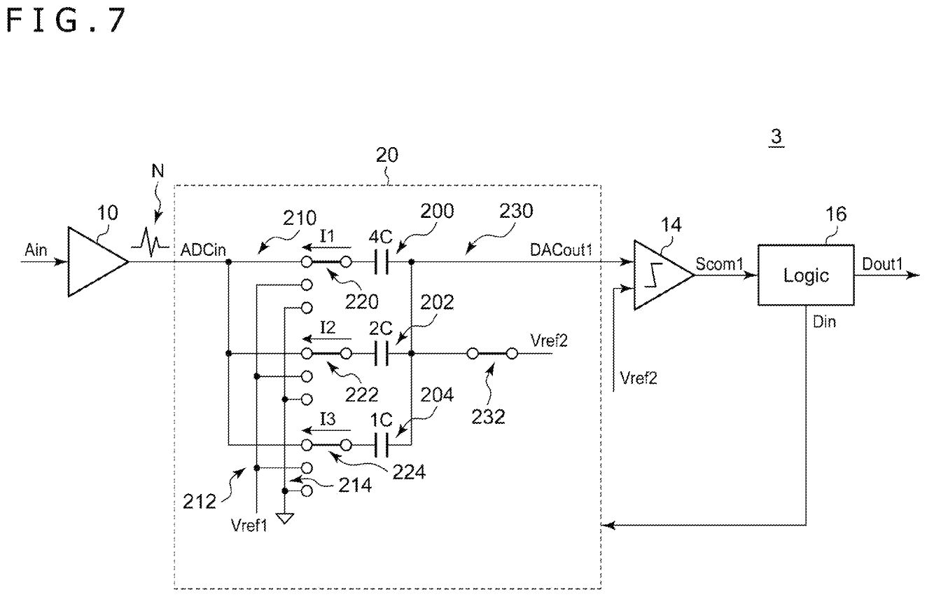

An example of operations of the successive approximation type ADC 3 of the comparative technology is described below with reference to FIGS. 5 through 7. FIG. 6 is a schematic diagram depicting the state of the successive approximation type ADC 3 of the comparative technology having terminated the successive approximation. FIG. 7 is a schematic diagram depicting the state of the successive approximation type ADC 3 of the comparative technology at the time of the next sampling.

First, the successive approximation type ADC 3 samples the analog signal ADCin corresponding to the analog input signal Ain. It is assumed here that the input signal Ain is 3 in hexadecimal (011). As depicted in FIG. 5, one end of each of the capacitors 200, 202, and 204 is connected to the input path 210, and the switch 232 connected to the output path 230 is turned on. This allows the output path 230 to be supplied with the comparison reference voltage Vref2, and causes the capacitors 200, 202, and 204 each to accumulate the electrical charges corresponding to the analog signal ADCin, thereby sampling the analog signal ADCin.

Thereafter, as with the above-described embodiment, the comparator 14 performs successive approximation of the output signal DACout1 of the capacitive DAC 20 and the comparison reference voltage Vref2, and generates a signal Scom1 reflecting the result of the successive approximation. Given the signal Scom1, the logic circuit 16 generates a digital output signal Dout1 reflecting the result of the successive approximation by the comparator 14.

FIG. 6 is a schematic diagram depicting the state of the successive approximation type ADC 3 of the comparative technology having terminated the successive approximation. As depicted in FIG. 6, the selectors 220, 222, and 224 are in a state of 3 in hexadecimal (011). Specifically, one end of the capacitor 200 is connected to the ground path 214, and one end of each of the capacitors 202 and 204 is connected to the reference path 212. The switch 232 is turned off.

As depicted in FIG. 7, at the time of the next sampling, one end of each of the capacitors 200, 202, and 204 is connected to the input path 210, and the switch 232 is turned on from the off-state. At this time, electrical charge flows I1, I2, and I3 left in the capacitors 200, 202, and 204 collide with the electrical charge flow corresponding to the analog signal ADCin, generating a kickback noise N. At this point, the larger the difference between the electrical charges accumulated in the capacitors 200, 202, and 204 just before the next sampling on one hand, and the electrical charges to be accumulated therein corresponding to the analog signal ADCin on the other hand the larger the kickback noise N that is generated. It takes time for the large kickback noise N to settle at the next sampling. To shorten the settling time requires configuring the buffer circuit 10 to respond rapidly, which entails increasing the current consumption of the buffer circuit 10 or widening the area allocated thereto.

By contrast, the successive approximation type ADC 1 of the above-described embodiment is capable of reducing the difference between the electrical charges accumulated in the capacitors 200, 202, and 204 just before the next sampling on one hand and the electrical charges to be accumulated therein corresponding to the analog signal ADCin on the other hand. This makes it possible to reduce the kickback noise N and shorten the settling time at the time of sampling.

### Supplementary Note

While a preferred embodiment of the present disclosure has been described using specific terms, such description is for illustrative purposes only to aid understanding and is not limitative of the scope of this disclosure or the claims that follow. The scope of this technology should be defined by the appended claims. Also, the scope of this technology includes not only the embodiment described above but also embodiments, working examples, and variations yet to be described in line with the spirit of the present disclosure.

### Additional Statement

One example of the technology disclosed in this description may be understood as follows.

### (Item 1)

A successive approximation type analog/digital converter for generating a digital output signal corresponding to an analog input signal, including:
a capacitive digital/analog converter including a plurality of capacitors covering the most significant bit through the least significant bit, sampling an analog signal corresponding to the input signal, and generating an analog output signal corresponding to a digital input;
a comparator performing successive approximation of the analog output signal for the most significant bit through the least significant bit and a comparison reference voltage; and
a control circuit generating the digital input corresponding to a result of the successive approximation by the comparator and generating the digital output signal corresponding to the sampled analog signal corresponding to the result of the successive approximation by the comparator,
in which the capacitive digital/analog converter samples the analog signal by allowing each of the capacitors to accumulate electrical charges corresponding to the input signal, and,
after the successive approximation by the comparator is performed and before the next sampling by the capacitive digital/analog converter is performed, the control circuit controls the electrical charges accumulated in each of the capacitors to become substantially equivalent to the electrical charges at the time of the preceding sampling.

### (Item 2)

The successive approximation type analog/digital converter according to Item 1, in which the capacitive digital/analog converter further includes an input path receiving input of the analog signal,
the analog signal is sampled by having one end of each of the capacitors supplied with the analog signal via the input path, and,
after the successive approximation by the comparator is performed and before the next sampling is performed, the control circuit causes one end of each of the capacitors to be short-circuited with each other.

### (Item 3)

The successive approximation type analog/digital converter according to Item 2, further including:
an input circuit generating the analog signal; and
a switch interposed between the input circuit and the input path,
in which, after the successive approximation by the comparator is performed and before the next sampling is performed, with the switch turned off, the control circuit connects one end of each of the capacitors to the input path.

### (Item 4)

The successive approximation type analog/digital converter according to Item 2 or 3, in which the capacitive digital/analog converter further includes an output path connected to the other end of each of the capacitors and outputting the analog output signal, and
the control circuit controls the capacitive digital/analog converter in such a manner that the output path is supplied with the comparison reference voltage at the time of the preceding sampling, the output path being further controlled to be supplied with the comparison reference voltage after the successive approximation by the comparator is performed and before the next sampling is performed.

The present disclosure thus provides a successive approximation type ADC that can shorten the settling time at the time of sampling.

What is claimed is:

1. A successive approximation type analog/digital converter for generating a digital output signal corresponding to an analog input signal, comprising:
a capacitive digital/analog converter including a plurality of capacitors covering a most significant bit through the least significant bit, sampling an analog signal corresponding to the input signal, and generating an analog output signal corresponding to a digital input;
a comparator performing successive approximation of the analog output signal for the most significant bit through the least significant bit and a comparison reference voltage; and
a control circuit generating the digital input corresponding to a result of the successive approximation by the comparator and generating the digital output signal corresponding to the sampled analog signal corresponding to the result of the successive approximation by the comparator,
wherein the capacitive digital/analog converter samples the analog signal by allowing each of the capacitors to accumulate electrical charges corresponding to the input signal, and,
after the successive approximation by the comparator is performed and before the next sampling by the capacitive digital/analog converter is performed, the control circuit controls the electrical charges accumulated in each of the capacitors to become substantially equivalent to the electrical charges at the time of the preceding sampling.

2. The successive approximation type analog/digital converter according to claim 1, wherein the capacitive digital/analog converter further includes an input path receiving input of the analog signal,
the analog signal is sampled by having one end of each of the capacitors supplied with the analog signal via the input path, and,
after the successive approximation by the comparator is performed and before the next sampling is performed, the control circuit causes one end of each of the capacitors to be short-circuited with each other.

3. The successive approximation type analog/digital converter according to claim 2, further comprising:
an input circuit generating the analog signal; and
a switch interposed between the input circuit and the input path,
wherein, after the successive approximation by the comparator is performed and before the next sampling is performed, with the switch turned off, the control circuit connects one end of each of the capacitors to the input path.

4. The successive approximation type analog/digital converter according to claim 2, wherein the capacitive digital/analog converter further includes an output path connected to the other end of each of the capacitors and outputting the analog output signal, and
the control circuit controls the capacitive digital/analog converter in such a manner that the output path is supplied with the comparison reference voltage at the time of the preceding sampling, the output path being further controlled to be supplied with the comparison reference voltage after the successive approximation by the comparator is performed and before the next sampling is performed.
